(19) United States
(12) Patent Application Publication
(10) Pub. No.: US 2024/0312790 A1
(43) Pub. Date: Sep. 19, 2024

(54) SELECTIVE ETCHING METHOD AND ETCHING ASSEMBLY

(71) Applicant: ASM IP Holding B.V., Almere (NL)

(72) Inventors: Eva Tois, Espoo (FI); Shaoren Deng, Ghent (BE); Daniele Chiappe, Freiburg (DE); Viraj Madhiwala, Heverlee (BE); Marko Tuominen, Helsinki (FI); Vincent Vandalon, Heverlee (BE)

(21) Appl. No.: 18/389,847

(22) Filed: Dec. 20, 2023

Related U.S. Application Data
(60) Provisional application No. 63/434,955, filed on Dec. 23, 2022.

(51) Int. Cl. H01L 21/311; H01L 21/67

(52) U.S. Cl. CPC H01L 21/31144; H01L 21/31111; H01L 21/67075; H01L 21/67086

(57) ABSTRACT

The current disclosure relates to methods of selectively etching a material. The method includes contacting a substrate having a first surface and a second surface with an etching liquid to selectively etch the first surface relative to the second surface, and the first surface comprises etchable material and the second surface is covered with a polyimide-comprising layer. The disclosure further relates to methods of forming a semiconductor device and to a semiconductor device. Further, the disclosure relates to methods of forming patterned features on a substrate, and to a semiconductor processing system.

### CROSS-REFERENCE TO RELATED APPLICATIONS

This application claims priority to and the benefit of U.S. Provisional Application No. 63/434,955, filed Dec. 23, 2022, the entirety of which is incorporated by reference herein.

### FIELD OF INVENTION

The present disclosure generally relates to methods and assemblies for processing semiconductor substrates. More particularly, the disclosure relates to methods and assemblies for selectively etching a particular material on a semiconductor substrate.

### BACKGROUND OF THE DISCLOSURE

Various dielectric, insulating and conductive materials are used in semiconductor applications as to form semiconductor devices and further integrated circuits. The growing complexity of the devices and device architectures necessitates the use of numerous processing steps, including repeated patterning, to create them. The cost of using different process steps is always a concern, and selective deposition of materials is being explored as an option to enable device scaling and/or increased performance while keeping the cost and complexity of the manufacturing process at bay.

Selective etching, in which specific materials are preferentially etched over other materials is emerging as a promising process to create multi-layered semiconductor structures without intermittent patterning. However, the selection of selective etching processes for various material combinations is limited. Thus, there is need in the art for more etching processes targeting new material combinations, and to improve the accuracy of the existing ones to enable further scalability and versatility semiconductor devices.

Any discussion, including discussion of problems and solutions, set forth in this section has been included in this disclosure solely for the purpose of providing a context for the present disclosure. Such discussion should not be taken as an admission that any of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter. Various embodiments of the present disclosure relate to methods of selectively etching material from a first surface of a substrate relative to a second surface of the same substrate. Embodiments of the current disclosure further relate to methods of forming patterned features on a substrate, to methods of fabricating semiconductor devices, and to semiconductor processing assemblies.

Various embodiments of the current disclosure relate to a method of selectively etching material from a first surface of a substrate relative to a second surface of the substrate. In one aspect, a method of selectively etching a material is disclosed. In the method, the substrate having a first surface and a second surface is contacted with an etching liquid to selectively etch the first surface relative to the second surface, and the first surface comprises etchable material and the second surface is covered with a polyimide-comprising layer.

In some embodiments, the etching liquid comprises an etchant selected from strong acids and nitrogen-containing hydroxides. In some embodiments, the etchant comprises a strong acid selected from a group consisting of HF, HCl and H₃PO₄. In some embodiments, the etchant comprises a nitrogen-containing hydroxide selected from NH₄OH and N(CH₃)₄OH. In some embodiments, the etching liquid comprises an accessory oxidizing agent. In some embodiments, the etching liquid is an aqueous solution.

In some embodiments, an etch ratio between the first surface and the polyimide-comprising layer is at least 10. In some embodiments, the polyimide-comprising layer is substantially not etched. In some embodiments, the method is performed at a temperature of between about 20° C. and about 100° C.

In some embodiments, the first surface and the second surface have chemically different composition. In some embodiments, the first surface comprises silicon. In some embodiments, the first surface comprises one or more of SiO₂, SiN, SiC, SiCN, SiON, SiOC and SiOCN.

In some embodiments, the second surface comprises a metal. In some embodiments, the metal is selected from a group consisting of aluminum, copper, tungsten, cobalt, nickel, niobium, iron, molybdenum, zinc, ruthenium, manganese, titanium, yttrium, tin and vanadium. In some embodiments, the second surface comprises one or more of an elemental metal, metal oxide, metal nitride.

In some embodiments, the first surface and the second surface form different surfaces of a structure. In some embodiments, the second surface forms a top surface of a gap.

In another aspect, a method of selectively etching material from a first surface of a substrate relative to a second surface of the substrate, and the method comprises providing the substrate having a first surface comprising an etchable material, and a second surface in a reaction chamber, and selectively depositing a layer comprising polyimide on the second surface by a cyclic deposition process. The cyclic deposition process comprises providing pyromellitic dianhydride and a diamine into the reaction chamber alternately and sequentially. The method further comprises providing the substrate in an etching space, wherein the etching space comprises an etching liquid to selectively etch the first surface. In some embodiments, the reaction chamber and the etching space are in the same processing assembly.

In a further aspect, a method of forming a semiconductor device comprising a selective etching process according to the current disclosure is disclosed.

In a yet further aspect, a semiconductor device formed by a method comprising a selective etching process according to the current disclosure is disclosed.

In an additional aspect, a method of forming a patterned feature on a substrate, the method comprising selectively etching material from a first surface of a substrate relative to a second surface of the substrate according to the current disclosure is disclosed.

In a yet another aspect, a semiconductor processing system for processing a substrate is disclosed. The processing system comprises an etching space constructed and arranged to hold a substrate having a first surface and a second surface, wherein the second surface is covered with a polyimide-comprising layer, a container for an etching liquid constructed and arranged to contain an etching liquid and means to expose the substrate to the etching liquid to selectively remove material from the first surface of the substrate. In some embodiments, the means to expose the substrate to the etching liquid is selected from a nozzle spray arrangement and an immersion arrangement.

### BRIEF DESCRIPTION OF THE DRAWINGS

The accompanying drawings, which are included to provide a further understanding of the disclosure and constitute a part of this specification, illustrate exemplary embodiments, and together with the description help to explain the principles of the disclosure. In the drawings:

FIG. 1A illustrates a step in a selective etching method according to the current disclosure.

FIG. 1B illustrates another step of a selective etching method according to the current disclosure.

FIG. 1C illustrates yet another step of a selective etching method according to the current disclosure.

FIG. 2 is a schematic drawing of an embodiment of a semiconductor processing system according to the current disclosure.

It will be appreciated that elements in the figures are illustrated for simplicity and clarity, and have not necessarily been drawn to scale. The illustrations presented herein are not meant to be actual views of any particular material, structure, or device, but are merely idealized representations that are used to describe embodiments of the disclosure. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

In various processing steps for semiconductor devices, certain areas of a substrate need to be removed. Patterning is time-consuming and expensive, and therefore, area-selective etching may be used as an alternative. However, high-fidelity etching is difficult to achieve, and new materials to form as etch-stop layers are sought after. Being able to selectively deposit such materials is a further complication of the selective etch approach. The inventors of the current disclosure developed methods to utilize polyimide-comprising, selectively depositable material to be used as an etch-stop or hard mask material that may be utilized for wet etching in a variety of contexts, including with different material combinations, as well as in three-dimensional semiconductor structures.

In one aspect, a method of selectively etching a material is disclosed. The material is selectively etched from a first surface of a substrate relative to a second surface of the same substrate. In the method, the substrate having a first surface and a second surface is contacted with an etching liquid to selectively etch the first surface relative to the second surface, and the first surface comprises etchable material and the second surface is covered with a polyimide-comprising layer.

By an etching liquid is herein meant an etchant-containing solution that is used in the liquid phase to etch, for example by dissolving, a material from the surface of a substrate. The material may be a material formed on a substrate or the substrate material itself. Thus, the current disclosure relates to wet etching.

Selective etching processes according to the current disclosure may be used to remove material from a substrate surface selectively. The material to be removed may be referred to as the etchable material. In some embodiments, the etchable material may be a material comprised in the substrate, or deposited on the substrate. In some embodiments, the etchable material has been deposited on the substrate on purpose. In some embodiments, the etchable material may be an unwanted contaminant on the substrate surface. For example, in some embodiments the etchable material to be etched is parasitic material grown unwantedly from an area-selective deposition process.

In the current disclosure, a polyimide-comprising layer covers the second surface of the substrate at the time of etching. By the polyimide-comprising layer covering the second surface is herein meant that a substantially pinhole-free layer having a thickness is positioned on the second surface but not on the first surface. The polyimide-comprising material may be formed on the second surface by a cyclic deposition process (molecular layer deposition, MLD). The selectivity of etching according to the current disclosure is determined by the polyimide-comprising layer. The material of the second surface below the polyimide-comprising layer may be susceptible to etching under the conditions described herein. The thickness of the polyimide-comprising layer may vary from application to application. For example, polyimide may be very resistant to various acids, such as HF. In such embodiments, even a thin polyimide-comprising layer is sufficient to protect the underlying material of the second surface. However, to achieve appropriate etch selectivity, the polyimide-comprising layer should be substantially pinhole-free to avoid areas of the second surface from being etched. Without limiting the current disclosure to any specific theory, the minimum thickness of the polyimide-comprising layer may be determined by the thickness in which a sufficiently continuous (pinhole-free) polyimide-comprising layer is achieved. In some embodiments, the polyimide-comprising layer has a thickness from about 1 nm to about 50 nm, such as from about 1 nm to about 30 nm, from about 1 nm to about 20 nm, from about 1 nm to about 10 nm or from about 1 nm to about 5 nm. In some embodiments, the polyimide-comprising layer has a thickness of about 2 nm, about 3 nm, about 4 nm or about 7 nm.

Further, the fidelity of etching depends on how accurately the polyimide-comprising layer is deposited on the second surface. Methods are known to those skilled in the art to regulate the accuracy of depositing a polyimide-comprising layer. For example, plasma treatment, such as hydrogen plasma treatment may be used to trim the edges of the polyimide-comprising layer, and methods directing the organic polymer on specific material or to a certain area of a three-dimensional structure are known in the art.

Selectivity in etching may be described as an etch ratio (i.e. etch selectivity), which is the ratio of etch rate of the material on the first surface relative to the etch rate of the material on the second surface. In the current disclosure, the material exposed to etching on the second surface is the polyimide-comprising layer covering the second surface. Thus, etch selectivity is to be understood as the selectivity between the first surface and the polyimide-comprising layer. In some embodiments, the polyimide-comprising layer is etched to a lesser extent than the first surface. In some embodiments, the etch selectivity of the process according to the current disclosure is about 2 or greater. For example, etch selectivity may be from about 2 to about 1,000, such as from about 2 to about 800, or from about 2 to about 500, or from about 2 to about 200, or from about 2 to about 100, or from about 2 to about 50. For example, the etch selectivity may be about 3, about 5, about 10, about 25 or about 40. In some embodiments, etch selectivity may be from about 5 to about 1,000, or from about 10 to about 1,000, or from about 50 to about 1,000, or from about 100 to about 1,000, or from about 500 to about 1,000. In some embodiments, an etch ratio between the first surface and the polyimide-comprising layer is at least 10. In some embodiments, the polyimide-comprising layer is substantially not etched. In such embodiments, etch selectivity may be difficult to assess.

The selective etching process according to the current disclosure is a continuous etching process. In some embodiments a substrate is contacted with the etching liquid as described herein for a sufficient time to achieve the desired level of etching. The substrate is contacted with an etching liquid to selectively etch the first surface relative to the second surface. As is known in the art, for example an immersion tank may be used for contacting the substrate with the etching liquid. In some cases, a spray system may be employed.

In some embodiments, the etchable material is etched at a speed from about 0.01 Å/s to about 4 Å/s, such as at a speed from about 0.1 Å/s to about 3 Å/s, or from about 0.05 Å/s to about 2 Å/s. In some embodiments, the etchable material is etched at a speed from about 0.05 Å/s to about 1 Å/s, or at a speed from about 1 Å/s to about 4 Å/s. In some embodiments, the etchable material is etched at a rate from about 1 Å/s to about 3 Å/s. The etching speed may depend on the composition of the etchable material. For example, aluminum oxide may be etched at a rate of about 1 to 2 Å/s by 0.5% HF. By 2 M HCl (i.e. approximately 7.3% (w/v)), the etch rate is about 0.02 Å/s. Yttrium oxide, on the other hand, is substantially not etched by 2 M HF, whereas with 2 M HCl, yttrium oxide is etched at a rate of about 1 Å/s. A polyimide-comprising material and layer is not etched under any of these conditions. The etching liquid concentrations are given in weight per volume percentages (w-%) unless otherwise indicated.

In some embodiments, the method according to the current disclosure is performed at a temperature of between about 20° C. and about 100° C. The selected temperature may affect the etching speed, and the temperature may be selected according to the application and other process parameters used. In some embodiments, the method is performed at a temperature between about 30° C. and about 100° C. or at a temperature between about 40° C. and about 100° C. In some embodiments, the method is performed at a temperature between about 50° C. and about 100° C. or at a temperature between about 70° C. and about 100° C. In some embodiments, the method is performed at a temperature between about 20° C. and about 70° C. or at a temperature between about 20° C. and about 50° C. or at a temperature between about 20° C. and about 30° C. In some embodiments, the method is performed at a temperature of between about 30° C. and about 80° C. or at a temperature between about 40° C. and about 65° C., such as at a temperature between about 50° C. and about 90° C. or at a temperature between about 50° C. and about 70° C.

### Etching Liquid

In the current disclosure, an etching liquid is used to etch the first surface of the substrate. Thus, one or more of the materials present in the first surface are susceptible to etching by the etchant present in the etching liquid. An etching liquid comprises an etchant and a solvent. The etching liquid may contain more than one etchant. As the current disclosure relates to wet etching, the etching liquid is in liquid phase during etching.

In some embodiments, the etching liquid is an aqueous solution. Thus, the solvent may be water. In some embodiments, the etching liquid is a non-aqueous solution. Thus the solvent may be a liquid other than water. For example, an organic solvent may be used. In some embodiments, the organic solvent is polar. An example of an organic solvent used for etchants is ethanol.

In some embodiments, the etching liquid comprises an etchant selected from strong acids and nitrogen-containing hydroxides. Examples of strong acids that may be used in the methods according to the current disclosure include HF, HCl and H₃PO₄. In some embodiments, the etchant comprises a strong acid selected from a group consisting of HF, HCl and H₃PO₄.

The method according to the current disclosure was tested by etching a substrate comprising silicon oxide as the first surface, and polyimide layer deposited on aluminum oxide and hafnium oxide as the second surface. However, the inventors have tested the deposition of polyimide-comprising materials to a large variety of materials, and many different alternatives as the second surface may be envisaged. Polyimide was deposited by molecular layer deposition at 170° C., using pyromellitic dianhydride and 1,6-diaminohexane as precursors. 0.5% (w/v) HF and 2 M HCl were used as etchants, and the etching was performed for up to 10 minutes for HF, and for up to 7 minutes for HCl at about 20° C. Neither of the etchants caused significant etching of the polyimide layer, as the thickness of the polyimide layer was reduced by about 1 nm at the most. Further, polyimide may be used as a passivation layer for area-selective deposition.

Even if a material is able to withstand etching, its surface properties may change during etching such that it loses its passive nature, and it can no longer be used to prevent a growth of a certain material on itself. This was tested by depositing aluminum oxide-containing material by atomic layer deposition on the substrate that had undergone etching. Dimethylaluminum isopropoxide and water were used as precursors. The passivation properties of the polyimide layer had been fully retained, and no aluminum oxide was detected over the polyimide layer, while about 6 nm of aluminum oxide was deposited on the first surface, i.e. silicon oxide. Further, no halogen was detected on the substate.

In some embodiments, the etchant is a nitrogen-containing hydroxide. The nitrogen-containing hydroxide may be ammonium hydroxide, or a hydroxide of an alkylammonium compound. In some embodiments, the alkylammonium compound is a tetraalkylammonium compound. In some embodiments, the etchant comprises a nitrogen-containing hydroxide selected from NH₄OH and N(CH₃)₄OH. For ammonium hydroxide, a 1:4:20 mixture of ammonium hydroxide, hydrogen peroxide and water was used as the etching liquid. The etching tests for this etching liquid were performed at a temperature of 65° C.

In some embodiments, the etching liquid comprises an accessory chemical. An accessory chemical may, for example, influence the etch rate, by increasing or decreasing it, or by stabilizing the etchant in the solution. In some embodiments, the etching liquid comprises an accessory oxidizing agent. In some embodiments, the accessory chemical is hydrogen peroxide (H₂O₂).

Different etchants may be used to etch different materials. For example, HF is one of rare etchants that etches silicon oxide. However, HF does not etch hafnium oxide. As indicated above, HF does not significantly etch polyimide-comprising material. HCl, on the other hand, does not etch silicon oxide or aluminum oxide, but it does etch yttrium oxide. Phosphoric acid (H₃PO₄) is able to etch aluminum oxide, but not silicon oxide. The varying etching capability combined with the possibility of selectively depositing a polyimide-comprising layer on various materials may enable the selective etching of a target material on a substrate comprising more than two layers of differing composition. For example, metals, such as copper, are typically sensitive to etching. On a substrate comprising, for example, copper, hafnium oxide, and silicon oxide surfaces, etching of only silicon oxide surface is not possible, unless the copper surface is protected by a polyimide-comprising layer.

The etchant concentration of the etching liquid may affect etching speed. In some embodiments, the etching liquid comprises between about 0.01% and about 20% etchant. Suitable etchant concentration depends on the etchant, and the material of the first surface. In some embodiments, the etching liquid comprises between about 0.01% and about 10% strong acid or between about 0.1% and about 5% strong acid, or between about 0.2% and about 8% strong acid or between about 0.3% and about 7% strong acid. In some embodiments, the etching liquid contains about 0.5% HF. In some embodiments, the etching liquid contains about 0.37% HCl.

In some embodiments, the etching liquid comprises between about 0.01% and about 10% nitrogen-containing hydroxide or between about 0.1% and about 5% nitrogen-containing hydroxide, or between about 0.2% and about 8% nitrogen-containing hydroxide or between about 0.3% and about 7% nitrogen-containing hydroxide. In some embodiments, the etching liquid contains about 4% NH₄OH.

### Polyimide-Comprising Layer

The polyimide-comprising layer covering the second surface serves to protect the second surface form being etched. Thus, the second surface being covered by the organic polymer is a not-etchable surface. The polyimide-comprising layer may, for example, comprise polyimide and polyamic acid. In some embodiments, the polyimide-comprising layer comprises primarily polyimide, such as at least about 50% polyimide. In some embodiments, the polyimide-comprising layer consists essentially of polyimide. In some embodiments, polyimide may be deposited at a temperature from about 150° C. to about 200° C., such as from about 170° C. to about 190° C. using 1,6-diaminohexane and pyromellitic dianhydride as precursors for the polymer formation.

A polyimide-comprising layer may be provided on the second surface by a cyclic deposition process. For example, polyimide-comprising layer may be deposited by providing an acid anhydride and a diamine alternately and sequentially into a reaction chamber to form a polyimide-comprising layer. The polyimide-comprising layer may be selectively deposited on the second surface by providing a two precursors, such as a diamine and an acid anhydride, into the reaction chamber alternately and sequentially. In some embodiments a diamine used to deposit the polyimide-comprising layer comprises 1,6-diaminohexane (DAH). In some embodiments the acid anhydride used to deposit the polyimide-comprising layer comprises a dianhydride. In some embodiments the dianhydride is pyromellitic dianhydride (PMDA). In some embodiments the substrate is held at a temperature of greater than about 80° C. or greater than about 170° C. during depositing the polyimide-comprising layer. For example, the polyimide-comprising layer may be deposited at a temperature of about 100° C., about 120° C., about 150° C., about 170° C., about 190° C., about 200° C. or about 220° C. In some embodiments, the polyimide-comprising layer comprises polyamide. In some embodiments the organic polymer that is selectively deposited is a mixture of polyamide, polyimide, and other polymeric material.

In some embodiments the polyimide-comprising layer is deposited on the second surface relative to the first surface with a selectivity of above about 50% or about 70% or above about 90% or about 95%. In some embodiments, the first surface is pretreated to improve the contrast between the first surface and the second surface and to drive the deposition of the polyimide-comprising layer on the second surface. For example, silylation may be used to pretreat the first surface. In some embodiments, a dielectric first surface is selectively silylated relative to the second surface. In some embodiments, the first surface is blocked from organic polymer deposition by exposure to a silylation agent, such as allyltrimethylsilane (TMS-A), chlorotrimethylsilane (TMS-Cl), N-(trimenthylsilyl)imidazole (TMS-Im), octadecyltrichlorosilane (ODTCS), hexamethyldisilazane (HMDS), or N-(trimethylsilyl)dimethylamine (TMSDMA).

In some embodiments, the blocking may aid in subsequent selective deposition of a polyimide-comprising layer on a second metal surface, as described below. Thus, blocking a dielectric surface may, in some embodiments, allow the selective deposition of an organic polymer on another surface, such as a metal surface or a dielectric surface of different composition. In some embodiments, blocking, such as silylation, does not require a specific removal step before an etching process according to the current disclosure.

In some embodiments, selective deposition of the polyimide-comprising layer on the second surface occurs at a growth rate of about 0.5 Å/cycle to about 20 Å/cycle, about 1 Å/cycle to about 15 Å/cycle, about 1.5 Å/cycle to about 10 Å/cycle, or about 2 Å/cycle to about 8 Å/cycle. In some embodiments the growth rate of the polyimide-comprising layer on the metal surface is more than about 0.5 Å/cycle, more than about 1 Å/cycle, more than about 3 Å/cycle, more than about 5 Å/cycle while on the upper end the growth rate in some embodiments is less than about 20 Å/cycle, less than about 15 Å/cycle, less than about 10 Å/cycle or less than about 8 Å/cycle. Selectivity for the metal surface relative to a second surface is maintained at these growth rates in some embodiments.

The thickness of the polyimide-comprising layer depends on the application. A thin polyimide-comprising layer is sufficient in embodiments, in which the polyimide-comprising layer is substantially not etched by the etching process according to the current disclosure. In embodiments in which the polyimide-comprising layer is etched by the etching process, a sufficiently thick layer is needed to keep the second surface protected from the etchant sufficiently long. However, it may be advantageous to continue etching long enough to remove the polyimide-comprising layer, as additional cleaning processes may be avoided. As described above, the minimum thickness needed for the polyimide-comprising layer may relate to the thickness at which a pinhole-free layer can be formed.

In some embodiments, the polyimide-comprising layer may be treated after deposition to improve its etch-resistance or other properties. In some embodiments, the substrate comprising the polyimide-comprising layer is heated for a period of about 1 minute to about 15 minutes. In some embodiments, the substrate is baked at a temperature of about 200° C. to about 500° C. Alternatively or in addition, the substrate comprising the polyimide-comprising layer may be treated with a curing agent, such as a dehydrating agent. In some embodiments, the substrate may be treated with acetic anhydride or other chemicals to increase the proportion of polyimide in the polyimide-comprising layer. However, in some embodiments, the polyimide-comprising layer is sufficiently etch-resistant as deposited, and no additional treatments are necessary.

### First Surface and Second Surface

In some embodiments, the first surface and the second surface have chemically different composition. However, in some embodiments, the first surface and the second surface form different surfaces of a structure. In such embodiments, the chemical composition of the first surface and the second surface may be the same or different.

According to some aspects of the present disclosure, selective etching can be used to remove material from a first surface of a substrate relative to a second surface of the substrate. The two surfaces may have different material properties.

### First Surface

In embodiments, in which the first surface and the second surface have different material properties, there are various alternatives to the surface composition. In some embodiments, the first surface comprises silicon. In some embodiments, the first surface comprises silicon. In some embodiments, the first surface comprises one or more of SiO₂, SiN, SiC, SiCN, SiON, SiOC and SiOCN.

As used herein, silicon oxide refers to a material that includes silicon and oxygen. Silicon oxide can be represented by the formula SiOx, where x can be between 0 and 2 (e.g., SiO₂). In some cases, the silicon oxide may not include stoichiometric silicon oxide. In some cases, the silicon oxide can include other elements, such as carbon, nitrogen (SiON), hydrogen, or the like.

Silicon carbide (SiC) can refer to a material that includes silicon and carbon. Silicon carbide need not necessarily be a stoichiometric composition. An amount of silicon can range from 5 to 50 at-%; an amount of carbon can range from about 50 to about 95 at-%. In some embodiments, SiC films may comprise one or more elements in addition to Si and C, such as H or N (SiCN).

Silicon nitride (SiN) can refer to a material that includes silicon and nitrogen. Silicon nitride need not necessarily be a stoichiometric composition, but may have stoichiometric composition, such as Si₃N₄. An amount of silicon can range from 5 to 50 at-%; an amount of nitrogen can range from about 50 to about 90 at-%. In some embodiments, SiN films may comprise one or more elements in addition to Si and N, such as H or C (SiCN).

Silicon oxycarbide (SiOC) can refer to material that comprises silicon, oxygen, and carbon. As used herein, unless stated otherwise, SiOC is not intended to limit, restrict, or define the bonding or chemical state, for example, the oxidation state of any of Si, O, C, and/or any other element in the film. In some embodiments, SiOC thin films may comprise one or more elements in addition to Si, O, and C, such as H or N. In some embodiments, the SiOC films may comprise Si—C bonds and/or Si—O bonds. In some embodiments, the SiOC films may comprise Si—C bonds and Si—O bonds and may not comprise Si—N bonds. In some embodiments, the SiOC films may comprise Si—H bonds in addition to Si—C and/or Si—O bonds. In some embodiments, the SiOC films may comprise more Si—O bonds than Si—C bonds, for example, a ratio of Si—O bonds to Si—C bonds may be from about 1:10 to about 10:1. In some embodiments, the SiOC films may comprise from about 0% to about 50% carbon on an atomic basis. In some embodiments, the SiOC films may comprise from about 0.1% to about 40%, from about 0.5% to about 30%, from about 1% to about 30%, or from about 5% to about 20% carbon on an atomic basis. In some embodiments, the SiOC films may comprise from about 0% to about 70% oxygen on an atomic basis. In some embodiments, the SiOC films may comprise from about 10% to about 70%, from about 15% to about 50%, or from about 20% to about 40% oxygen on an atomic basis. In some embodiments, the SiOC films may comprise about 0% to about 50% silicon on an atomic basis. In some embodiments, the SiOC films may comprise from about 10% to about 50%, from about 15% to about 40%, or from about 20% to about 35% silicon on an atomic basis. In some embodiments, the SiOC films may comprise from about 0.1% to about 40%, from about 0.5% to about 30%, from about 1% to about 30%, or from about 5% to about 20% hydrogen on an atomic basis. In some embodiments, the SiOC films may not comprise nitrogen. In some other embodiments, the SiOC films may comprise from about 0% to about 40% nitrogen on an atomic basis (at-%). By way of particular examples, SiOC films can be or include a layer comprising SiOCN. In some embodiments, silicon oxycarbide can be represented by the chemical formula Si_{z}OₓC_{y}, where z can range from about 0 to about 2, x can range from about 0 to about 2, and y can range from about 0 to about 5.

Silicon oxycarbonitride (SiOCN) refers to material that comprises silicon, oxygen, nitrogen and carbon. As used herein, unless stated otherwise, SiOCN is not intended to limit, restrict, or define the bonding or chemical state, for example, the oxidation state of any of Si, O, C, N and/or any other element in the film. In some embodiments, SiOCN is material that can be represented by the chemical formula Si_{z}OₓC_{y}N_{w}, where z can range from about 0 to about 2, x can range from about 0 to about 2, y can range from about 0 to about 2, and w can range from about 0 to about 2.

In some embodiments, the first surface is a dielectric surface. In some embodiments, the first surface is a low-k surface. In some embodiments, the first surface comprises an oxide. In some embodiments, the first surface comprises a nitride. In some embodiments, the first surface comprises silicon. Examples of silicon-comprising dielectric materials include silicon oxide-based materials, including grown or deposited silicon dioxide, doped and/or porous oxides and native oxide on silicon. In some embodiments, the first surface comprises one or more of SiO₂, SiN, SiC, SiCN, SiON, SiOC and SiOCN. In some embodiments, the first surface comprises silicon oxide. In some embodiments, the first surface is a silicon oxide surface, such as a native oxide surface, a thermal oxide surface or a chemical oxide surface. In some embodiments, the first surface comprises silicon oxide-based material. In some embodiments, the first surface comprises SiN. In some embodiments, the first surface comprises carbon. In some embodiments, the first surface comprises SiOC.

In some embodiments, the first surface comprises a metal oxide. For example, the metal oxide may be a high k metal oxide. Thus, in some embodiments, a first metal oxide surface is selectively etched relative to a second surface covered by a polyimide-comprising layer. A metal oxide surface may be, for example a tungsten oxide (WOx) surface, hafnium oxide (HfOx) surface, titanium oxide (TiOx) surface, aluminum oxide (AlOx) surface or zirconium oxide (ZrOx) surface, or a combination thereof. In some embodiments, the first surface is a metal oxide surface selected from aluminum oxide, hafnium oxide, zirconium oxide, lanthanum oxide and combinations thereof. In some embodiments, a metal oxide surface is an oxidized surface of a metallic material. In some embodiments, a metal oxide surface is created by oxidizing at least the surface of a metallic material using oxygen compound, such as compounds comprising O₃, H₂O, H₂O₂, O₂, oxygen atoms, plasma or radicals or mixtures thereof. In some embodiments, a metal oxide surface is a native oxide formed on a metallic material.

In some embodiments, the first surface comprises hydroxyl (—OH) groups. In some embodiments, the first surface may additionally comprise hydrogen (—H) terminations, such as an HF dipped Si or HF dipped Ge surface.

In some embodiments, a first dielectric surface of a substrate is selectively etched relative to a second, different dielectric surface of the substrate. In some such embodiments, the dielectric surfaces have different compositions (e.g., silicon, silicon nitride, carbon, silicon oxide, silicon oxynitride, germanium oxide). In some embodiments, a passivation blocking agents, such as silylation, is used to improve contrast between two dielectric surfaces before depositing a passivation layer on the first surface.

The term dielectric is used in the description herein for the sake of simplicity in distinguishing from the other surface, namely the metal or metallic surface. It will be understood by those skilled in the art that not all non-conducting surfaces are dielectric surfaces. For example, the metal or metallic surface may comprise an oxidized metal surface that is electrically non-conducting or has a very high resistivity.

In some embodiments, material of the first dielectric surface of a substrate is etched relative to a second metal or metallic surface of the substrate. In some embodiments, a first dielectric surface of a substrate is selectively etched relative to a second conductive (e.g., metal or metallic) surface of the substrate. In some embodiments the first surface and the second surface are adjacent to each other.

### Second Surface

In some embodiments, the second surface comprises a metal. In some embodiments, the first surface comprises a metal oxide. The term metal oxide can refer to metal that includes a metal and oxygen. The metal or can be, for example, one or more of aluminum, titanium, tin, hafnium, zirconium, indium, cesium, molybdenum, copper, cobalt, ruthenium, tungsten, zinc, nickel, vanadium and niobium.

In some embodiments, the second surface may comprise a metal surface covered by a polyimide-comprising layer, for example a Cu surface covered by a polyimide-comprising layer. That is, in some embodiments, the second surface may comprise a metal surface covered by a polyimide-comprising layer such as a polyimide layer. In some embodiments, the second surface comprises a metal oxide, elemental metal, or metallic surface. In some embodiments, the second metal or metallic surface comprises a polyimide-comprising layer comprising polyamic acid, polyimide, or other polymeric material.

In some embodiments a polyimide-comprising layer such as a polyamide, polyimide or a combination thereof, optionally including other polymers, is selectively deposited on a second dielectric surface of a substrate relative to a first, different dielectric surface. In some such embodiments, the dielectrics have different compositions (e.g., silicon, silicon nitride, carbon, silicon oxide, silicon oxynitride, germanium oxide).

In some embodiments, the second surface comprises a metal. In some embodiments, the second surface comprises metallic material.

For embodiments in which a surface of the substrate comprises a metal, the surface is referred to as a metal surface. In some embodiments, a metal surface consists essentially of, or consists of one or more metals. A metal surface may be a metal surface or a metallic surface. In some embodiments the metal or metallic surface may comprise metal, metal oxides, and/or mixtures thereof. In some embodiments the metal or metallic surface may comprise surface oxidation. In some embodiments the metal or metallic material of the metal or metallic surface is electrically conductive with or without surface oxidation. In some embodiments, metal or a metallic surface comprises one or more transition metals. In some embodiments, the metal or metallic surface comprises one or more transition metals from row 4 of the periodic table of elements. In some embodiments, the metal or metallic surface comprises one or more transition metals from groups 4 to 11 of the periodic table of elements. In some embodiments, a metal or metallic surface comprises aluminum (Al). In some embodiments, a metal or metallic surface comprises copper (Cu). In some embodiments, a metal or metallic surface comprises tungsten (W). In some embodiments, a metal or metallic surface comprises cobalt (Co). In some embodiments, a metal or metallic surface comprises nickel (Ni). In some embodiments, a metal or metallic surface comprises niobium (Nb). In some embodiments, the metal or metallic surface comprises iron (Fe). In some embodiments, the metal or metallic surface comprises molybdenum (Mo). In some embodiments, the metal or metallic surface comprises zinc (Zn). In some embodiments, the metal or metallic surface comprises ruthenium (Ru). In some embodiments, the metal or metallic surface comprises manganese (Mn). In some embodiments, the metal or metallic surface comprises titanium (Ti). In some embodiments, the metal or metallic surface comprises tin (Sn). In some embodiments, the metal or metallic surface comprises vanadium (V). In some embodiments, a metal or metallic surface comprises a metal selected from a group consisting of Al, Mn, Fe, Co, Ni, Cu, Zn, Nb, Mo, Ru and W. In some embodiments, the metal or metallic surface comprises a transition metal selected from a group consisting of Zn, Fe, Mn and Mo. In some embodiments, the metal or metallic surface comprises a metal selected from a group consisting of Cu, Co, Ru, W and Mo.

In some embodiments, a metallic surface comprises titanium nitride. In some embodiments, the metal or metallic surface comprises one or more noble metals, such as Ru. In some embodiments, the metal or metallic surface comprises a conductive metal oxide. In some embodiments, the metal or metallic surface comprises a conductive metal nitride. In some embodiments, the metal or metallic surface comprises a conductive metal carbide. In some embodiments, the metal or metallic surface comprises a conductive metal boride. In some embodiments, the metal or metallic surface comprises a combination conductive materials. For example, the metal or metallic surface may comprise one or more of ruthenium oxide (RuOx), niobium carbide (NbCx), niobium boride (NbBx), nickel oxide (NiOx), cobalt oxide (CoOx), niobium oxide (NbOx), tungsten carbonitride (WNCx), tantalum nitride (TaN), or titanium nitride (TiN).

In some embodiments, the second surface is a metal surface, wherein the metal is selected from a group consisting of Al, Cu, W, Co, Ni, Nb, Fe, Mo, Zn, Ru, Mn, Ti, Sn and V. In some embodiments, the second surface comprises one or more of an elemental metal, metal oxide, metal nitride. In some embodiments, the polyimide-comprising layer on a metal or metallic surface inhibits, prevents or reduces the etching of the material of the metal or metallic surface. In some embodiments, the second surface comprises silicon germanium (SiGe). In some embodiments, the second surface is a SiGe surface.

In some embodiments, the second surface comprises a metal oxide, metal nitride, elemental metal, or metallic surface. The second surface is covered with a polyimide-comprising layer comprising polyamic acid, polyimide, and/or other polymeric material.

In some embodiments, the second surface comprises carbon. In some embodiments, the second surface comprises amorphous carbon. In some embodiments, the second surface comprises at least about 50 at-% carbon. In some embodiments, the second surface comprises amorphous carbon (amorphous carbon surface). In some embodiments, the second surface consists substantially of, or consist of, amorphous carbon. For example, the first surface may be a silicon-containing surface, such as a low k surface, and the second surface may be an amorphous carbon surface. In some embodiments, the second surface comprises spin-on carbon. In some embodiments, amorphous carbon is deposited by cyclic plasma-enhanced deposition methods. For example, amorphous carbon may be deposited using plasma-enhanced chemical vapor deposition (PE-CVD) or plasma-enhanced atomic layer deposition (PE-ALD). In some embodiments, the second surface substantially consists of spin-on carbon. For example, the spin-on carbon may be a hard mask for patterning.

### Structures

In some embodiments, the first surface and the second surface form different surfaces of a structure. In some embodiments, the second surface forms an inside surface of a gap. The inside surface may have the same or a different material composition than other surfaces of the structure. A gap comprises a side wall, and the polyimide-comprising layer may cover a side wall of the gap. A gap may comprise a bottom, and the polyimide-comprising layer may cover the bottom of the gap. The gap may be filled with the polyimide-comprising layer, or the polyimide-comprising layer may conformally cover at least a side wall or a bottom of the gap.

A gap in this disclosure is in or on a substrate. A gap is to be understood to describe a change in the surface topology of the substrate leading to some areas of the substrate surface being lower than other areas. Gaps thus include topologies in which parts of the substrate surface are lower relative to the majority of the substrate surface. These include trenches, vias, recesses, valleys, crevices and the like. Further, also areas between elevated features protruding upwards of the majority of the substrate surface form gaps. Thus, the space between adjacent fins is considered a gap. A gap may comprise a top and a bottom. An upper part of a gap is the area at the opening of the gap, and the bottom of the gap is the part of the gap distal to the opening of the gap. The area outside the gap is termed the top surface of a gap, such as the topmost horizontal part of a fin, or an area of the substrate between holes or vias.

In some embodiments, in which the second surface forms an inside surface of a gap, the gap may be filled with the polyimide-comprising layer. The filling may be non-selective by selecting the deposition conditions of the polyimide-comprising layer appropriately. The polyimide-comprising layer maybe then removed by, for example, plasma treatment, such as hydrogen plasma treatment, until the top surface of the structure is exposed.

In some embodiments, the polyimide-comprising layer is deposited to substantially fill a gap in the substrate. In some embodiments, the polyimide-comprising layer is deposited until its surface is substantially flush with the top surface of the gap. In some embodiments, the polyimide-comprising layer is deposited until it grows out of the gap. In some embodiments, the polyimide-comprising layer is not deposited laterally outside the gap. In some embodiments, the polyimide-comprising layer is deposited laterally outside the gap. In some embodiments, the method according to the current disclosure comprises an etch-back phase to adjust the surface of the polyimide-comprising layer. In some embodiments, trimming of the substrate after depositing polyimide-comprising layer comprises an etch-back of the polyimide-comprising layer.

The purpose of depositing polyimide-comprising layer inside the gap is to avoid the etching of the material in the gap. The polyimide-comprising layer is a sacrificial material that is not necessarily present in the final structure or device according to the current disclosure. Therefore, the deposition of the polyimide-comprising layer does not need to be uniform in the gap, and the deposition of the polyimide-comprising layer does not need to fill the gap completely. Therefore, the polyimide-comprising layer may form an air gap in the gap. In other words, the gap can be pinched off by the growth of the polyimide-comprising layer, leaving an empty cavity inside the gap. Without limiting the current disclosure to any specific theory, gravity or other physical conditions may affect the polyimide-comprising layer also after deposition. Thus, in some embodiments, the polyimide-comprising layer may collapse, or otherwise deform so that the cavity is not visible, or present. Further, the surface of the polyimide-comprising layer may be concave or otherwise uneven. In some embodiments, the inner surface of the gap comprises material on which the organic polymer can be selectively grown as described above. However, also materials on which the organic polymer does not grow selectively on under the deposition conditions in question may be present on the inside surface of the gap. The polyimide-comprising layer may or may not be deposited on such additional materials. For example, in some embodiments, same material as on the first surface (i.e. top surface) may be present on the inside of the gap. However, the polyimide-comprising layer is inherently deposited on itself. It may therefore reach the top of the gap even in embodiment in which the inside surface of the gap contains materials on which the polyimide-comprising layer does not deposit.

In some embodiments, the polyimide-comprising layer is deposited substantially conformally on a side wall of the gap. In some embodiments, the polyimide-comprising layer is deposited on the side wall of a gap, and not on the bottom of the gap. For example, the bottom of the gap may comprise material on which the organic polymer does not grow under the deposition conditions in question, whereas the side wall contain material on which the polyimide-comprising layer grows.

In some embodiments, the second surface forms a top surface of a gap. The top surface of a gap may be a horizontal surface. For example, a pretreatment described above may be performed to block the growth of the polyimide-comprising layer on the substrate by silylation. The blocking may be selectively removed from the top surface of the structure by a plasma treatment, for example. This will allow the growth of the organic polymer on the top surface but not on the inside surface of the gap, such as on the side walls. Consequently, the top surface will form the second surface and is protected from etching, whereas the areas from which the blocking, such as silylation, is removed, are exposed to etching. Further, if the blocking has been formed on both the top surface and the bottom of the gap, which extend in the same horizontal direction, the intensity of the removal of blocking may be adjusted to remove the blocking only from the top surface and to keep the bottom of the gap blocked from being covered by the polyimide-comprising layer.

In another aspect, a method of selectively etching material from a first surface of a substrate relative to a second surface of the substrate, and the method comprises providing the substrate having a first surface comprising an etchable material, and a second surface in a reaction chamber, and selectively depositing a polyimide-comprising layer on the second surface by a cyclic deposition process. The cyclic deposition process comprises providing pyromellitic dianhydride and a diamine into the reaction chamber alternately and sequentially. The method further comprises providing the substrate in an etching space, wherein the etching space comprises an etching liquid to selectively etch the first surface. In some embodiments, the reaction chamber and the etching space are in the same processing assembly. In a further embodiment, a method of forming a semiconductor device comprising a selective etching process according to the current disclosure is disclosed.

### Reaction Chamber and Deposition Assembly

In some embodiments, the current selective etching method is used as a part of a process for manufacturing a semiconductor device. Accordingly, a semiconductor device formed by a method comprising a selective etching process according to the current disclosure is disclosed. The manufacturing process may involve forming a feature, such as a patterned feature. In a yet further aspect, a method of forming a patterned feature on a substrate is disclosed. The method comprises selectively etching material from a first surface of a substrate relative to a second surface of the substrate according to the current disclosure. Also, a method of forming a structure comprising a selective etching process according to the current disclosure is disclosed. The manufacturing process may comprise one or more vapor deposition processes. It may be advantageous to combine the one or more vapor deposition processes with the current selective etching method in one semiconductor processing assembly.

In a yet another aspect, a semiconductor processing system for processing a substrate is disclosed. The processing system comprises an etching space constructed and arranged to hold a substrate having a first surface and a second surface, wherein the second surface is covered with a polyimide-comprising layer, a container for an etching liquid constructed and arranged to contain an etching liquid and means to expose the substrate to the etching liquid to selectively remove material from the first surface of the substrate. In some embodiments, the means to expose the substrate to the etching liquid is selected from a nozzle spray arrangement and an immersion arrangement. In some embodiments, the semiconductor processing system according to the current disclosure comprises a computer programmed to deposit the organic polymer on the second surface before the etching process according to the current disclosure.

### DRAWINGS

The disclosure is further explained by the following exemplary embodiments depicted in the drawings. The illustrations presented herein are not meant to be actual views of any particular material, structure, or assembly, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. Specifically, relative etch rates of different materials indicated in the drawings may deviate from the experimental results, the specifics of which may vary according to process conditions. The structures, devices and assemblies depicted in the drawings may contain additional elements and details, which may be omitted for clarity.

For the sake of brevity, conventional manufacturing, connection, preparation, and other functional aspects of the methods and systems described herein may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

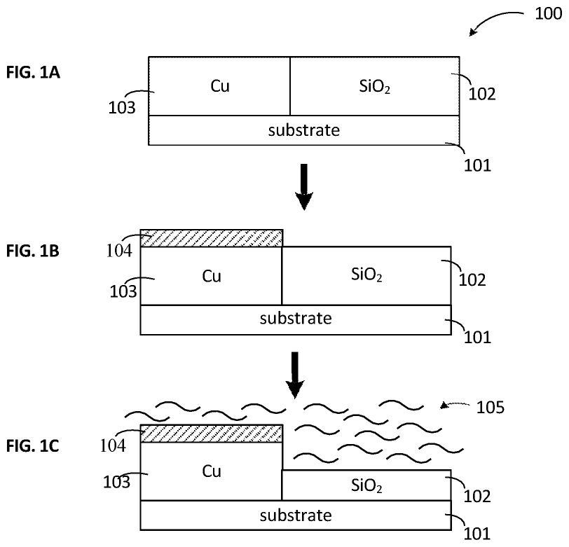

FIGS. 1A-C illustrate an exemplary embodiment of a selective etching method 100 according to the current disclosure in a schematic form. Method 100 may be used to selectively etch a first material relative to a second material from a substrate. The etching method 100 can be used during a formation of a semiconductor structure or device.

In FIG. 1A, a substrate 101 comprising a first silicon dioxide surface 102 and a second Cu surface 103 is displayed. Although Cu is depicted as an example of a metal material in the figure, several other materials, such as metals or metallic materials, could be used in place of, or in combination with, Cu. Additionally, polyimide-comprising material can be selectively deposited on amorphous carbon surfaces. Thus, amorphous carbon could be used in place of Cu on the second surface 103. The first surface is a silicon oxide surface, but similarly to the second surface 103, various alternatives, as disclosed herein, are possible. The etching space and the corresponding semiconductor processing apparatus may be as described above. The first surface and the second surface may be substantially on the same vertical level, or they can be at different heights relative to the substrate surface. The two surfaces may further be two surfaces in a 3D structure. For example, the first surface may form a bottom of a gap, whereas the second surface may form a side wall of the gap.

In FIG. 1B, the polyimide-comprising layer 104 has been deposited on the second surface 103 of the substrate 101. The deposition may be performed in a separate deposition assembly that is connected to an etching system. Alternatively, the deposition of the polyimide-comprising layer 104 may be performed in a separate deposition assembly. The polyimide-comprising layer 104 covering the second surface 103 may protect the second surface 103 from ambient atmosphere. For example, oxidation of the second surface 103 may be prevented or reduced by the polyimide-comprising layer 104.

The substrate 101 as depicted in panel b) is provided in an etching space of a semiconductor processing system. The etching space can be provided with temperature regulation device, such as a heater to activate the reactions by elevating the temperature of the etching liquid and/or the substrate being processed.

At FIG. 1C, etching liquid 105 (indicated by the wavy lines) is provided into the etching space to contact the substrate 101 and to etch the material of the first surface 102. The polyimide-comprising layer 104 and the second surface 103 under it stay substantially intact.

The substrate 101 can be brought to a desired temperature for contacting it with an etching liquid 105 prior to contacting it with the etching liquid. Alternatively or in addition, the etching liquid may be present in the etching space already before the substrate 101 is brought in the space. Further, the contact with the etching liquid 105 may be sufficient regulation of the processing temperature. A temperature (e.g., of a substrate and/or the etching liquid) within an etching space can be, for example, from about 20° C. to about 100° C., from about 20° C. to about 80° C., from about 20° C. to about 70° C., from about 30° C. to about 90° C., from about 40° C. to about 80° C. or from about 30° C. to about 40° C. Exemplary temperatures within the etching space may be about 20° C. for HF and HCl, about 65° C. for NH₄OH and about 80° C. for N(CH₃)₄OH.

The duration of contacting the substrate 101 with the etching liquid 105 (etching time) may depend on the thickness and etching speed of the first layer 102. In some embodiments, the substrate 101 is contacted with the etching liquid for, for example, from about 0.5 seconds to about 20 minutes, or from about 15 seconds to about 10 minutes. The duration of contacting the substrate with the etching liquid (etching time) is selected based on the materials, temperature, depth of the desired etching and other factors. In some embodiments, contacting the etching time is from about 1 second to about 1 minute, or from about 1 second to about 5 minutes, or from about 1 second to about 10 minutes or from about 30 seconds to about 10 minutes, or from about 1 minute to about 8 minutes or from about 1 minute to about 5 minutes. In some embodiments, the etching time is shorter than about 10 minutes, or shorter than about 7 minutes. In some embodiments, the etching time may be longer than about 30 seconds or longer than about 1 minute or longer than about 3 minutes, or longer than about 5 minutes.

Although not depicted in the drawing, the process may need to be optimized to avoid forming undercuts. The isotropic etching effects may also depend on the topology of the etched structure, which is not indicated in the schematic drawing. After the etching process, the polyimide-comprising layer 104 may be removed, or the substrate processing may be continued using the polyimide-comprising layer 104 further. Advantageously, the polyimide-comprising layer 104 may be utilized in area-selective deposition processes to direct deposition on the (etched) first surface 102.

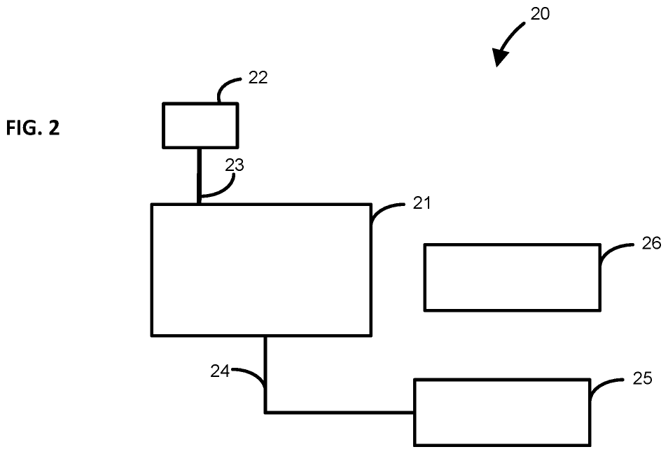

FIG. 2 illustrates an exemplary embodiment of a semiconductor processing system 200 according to the current disclosure. As a schematic representation of a semiconductor processing system 20, many components have been omitted for simplicity of illustration, and such components may include, for example, various inlets, outlets, valves, manifolds, purifiers, heaters, containers, vents, and/or bypasses.

The semiconductor processing system 20 comprises an etching space 21, an etching liquid reservoir 22 for holding etching liquid, an inlet 23 for providing an etching liquid into the etching space 21, and a outlet 24 for removing etching liquid from the etching space 21.

The etching space 21 may be an etching tank. An etching tank may be a receptacle for etching liquid into which the substrate is submerged. An etching tank may comprise etching liquid overflow systems, such as an outer tank or a second outlet (not depicted). In some embodiments, the etching space 21 may be a spray chamber for spraying the substrate with the etching liquid. In such embodiments, the semiconductor processing system comprises liquid piping, nozzles, valves etc. for regulating the etching liquid flow into the etching space 21.

The etching space 21 may be configured and arranged for holding one substrate. Alternatively, the etching space 21 may be configured and arranged for holding two or more substrates.

The liquid reservoir 22 is configured and arranged to hold an etching liquid according to the current disclosure. In some embodiments, the semiconductor processing system 20 comprises a second or a further liquid reservoir (not depicted). For example, additional oxidizing or other accessory agents may be stored in a second liquid reservoir, and an accessory agent can mixed with the etching liquid as needed.

Used etching liquid may be removed from the etching space 21 through an outlet 24. The used etching liquid may be collected in a disposal reservoir 25.

The embodiment of a semiconductor processing system of FIG. 2 additionally comprises a controller 26. The controller 26 includes electronic circuitry and software to selectively operate valves, manifolds, heaters, pumps and other components included in the semiconductor processing system 20. Such circuitry and components operate to provide liquids, regulate temperature, pressure etc. to provide proper operation of the semiconductor processing system 20. Controller 26 can include modules such as a software or hardware component, which performs certain tasks. A module may be configured to reside on the addressable storage medium of the control system and be configured to execute one or more processes.

During operation of semiconductor processing system 20, one or more substrates, such as semiconductor wafers (not illustrated), are transferred to etching space 21. Depending on the configuration of the system 20, etching liquid is provided into the etching space 21, or the substrate(s) make contact with etching liquid previously present in the etching space 21.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various methods and assemblies, and other features, functions, acts, and/or properties disclosed herein, as well as any and all equivalents thereof.

1. A method of selectively etching a material, the method comprising:
contacting a substrate having a first surface and a second surface with an etching liquid to selectively etch the first surface relative to the second surface, wherein the first surface comprises etchable material and the second surface is covered with a polyimide-comprising layer.

2. The method of claim 1, wherein the etching liquid comprises an etchant selected from the group consisting of strong acids and nitrogen-containing hydroxides.

3. The method of claim 1, wherein the etchant comprises a strong acid selected from a group consisting of HF, HCl and H₃PO₄.

4. The method of claim 2, wherein the etchant comprises a nitrogen-containing hydroxide selected from the group consisting of NH₄OH and N(CH₃)₄OH.

5. The method of claim 1, wherein the etching liquid comprises an accessory oxidizing agent.

6. The method of claim 1, wherein the etching liquid is an aqueous solution.

7. The method of claim 1, wherein an etch ratio between the first surface and the polyimide-comprising layer is at least 10.

8. The method of claim 1, wherein the polyimide-comprising layer is substantially not etched.

9. The method of claim 1, wherein the first surface and the second surface have a chemically different composition.

10. The method of claim 1, wherein the first surface comprises silicon.

11. The method of claim 10, wherein the first surface comprises one or more of SiO₂, SiN, SiC, SiCN, SiON, SiOC, or SiOCN.

12. The method of claim 10, wherein the second surface comprises a metal.

13. The method of claim 12, wherein the metal is selected from the group consisting of aluminum, copper, tungsten, cobalt, nickel, niobium, iron, molybdenum, zinc, ruthenium, manganese, titanium, yttrium, tin, and vanadium.

14. The method of claim 12, wherein the second surface comprises one or more of an elemental metal, metal oxide, metal nitride.

15. The method of claim 1, wherein the first surface and the second surface form different surfaces of a structure.

16. The method of claim 15, wherein the second surface forms a top surface of a gap.

17. A method of selectively etching material from a first surface of a substrate relative to a second surface of the substrate, the method comprising:
providing a substrate having a first surface comprising an etchable material, and a second surface, in a reaction chamber;
selectively depositing a layer comprising polyimide on the second surface by a cyclic deposition process, wherein the cyclic deposition process comprises:
providing pyromellitic dianhydride and a diamine into the reaction chamber alternately and sequentially; and
providing the substrate in an etching space, wherein the etching space comprises an etching liquid to selectively etch the first surface.

18. The method of claim 17, wherein the reaction chamber and the etching space are in the same processing assembly.

19. A semiconductor processing system for processing a substrate, the processing system comprising:
an etching space constructed and arranged to hold a substrate having a first surface and a second surface, wherein the second surface is covered with a polyimide-comprising layer;
a container for an etching liquid constructed and arranged to contain an etching liquid; and
means to expose the substrate to the etching liquid to selectively remove material from the first surface of the substrate.

20. The semiconductor processing system of claim 19, wherein the means to expose the substrate to the etching liquid is selected from the group consisting of a nozzle spray arrangement and an immersion arrangement.
